(19) United States
(12) Patent Application Publication
(10) Pub. No.: US 2022/0068518 A1
(43) Pub. Date: Mar. 3, 2022

(54) METHOD OF MANUFACTURING AN ELECTRONIC DEVICE AND CONDUCTIVE PASTE FOR THE SAME

(71) Applicant: DUPONT POLYMERS, INC., WILMINGTON, DE (US)

(72) Inventors: YUKA YOSHIIKE, TOKYO (JP); YUMI MATSUURA, KANAGAWA (JP)

(21) Appl. No.: 17/454,098

(22) Filed: Nov. 9, 2021

Related U.S. Application Data
(63) Continuation of application No. 16/288,040, filed on Feb. 27, 2019.

(30) Foreign Application Priority Data
Mar. 2, 2018 (JP) 2018-037566

(51) Int. Cl. H01B 1/22; H01L 23/00; C09D 135/08; C08L 25/08; C08L 35/08; H05K 1/09; C09J 135/08; C09D 5/24

(52) U.S. Cl. CPC H01B 1/22; H01L 24/83; H01L 24/29; C09D 135/08; C08L 25/08; C08K 2003/0806; H05K 1/092; C09J 135/08; C09D 5/24; H01L 2224/83862; H01L 2224/2919; C08L 35/08

(57) ABSTRACT

The invention relates to a method of manufacturing an electronic device comprising the steps of: preparing a substrate comprising an electrically conductive layer; applying a conductive paste on the electrically conductive layer, wherein the conductive paste comprises 100 parts by weight of a metal powder, 5 to 20 parts by weight of a solvent and 0.01 to 5 parts by weight of a dispersant and wherein the dispersant is selected from the group consisting of allyl ether copolymer, polyhydroxy fatty acid and a mixture thereof; mounting an electrical component on the applied conductive paste; and heating the conductive paste to bond the electrically conductive layer and the electrical component.

### FIELD OF THE INVENTION

The present invention relates to a conductive paste for bonding and a method for manufacturing an electronic device using the conductive paste.

### TECHNICAL BACKGROUND OF THE INVENTION

An electronic device comprises an electrical component such as a semiconductor chip that is bonded to an electrically conductive layer of a substrate using a conductive paste.

In this approach, the electrical component is physically and electrically connected to the electrically conductive layer by applying conductive paste onto the electrically conductive layer, mounting the electrical component on the conductive paste, and then heating the conductive paste. It has been found that when manufacturing processes do not provide sufficient adhesion between the mounted electrical component and the conductive paste layer before boding during manufacturing process, so that the electrical component may peel off and cause defects in the electronic device.

JP2014-235942 discloses a jointing material which prevents formation of aggregate on the surface of a copper substrate immediately after coating or after the lapse of a specified time from coating and prevents deterioration of the jointing power due to occurrence of cracks in a pre-dried film and a method of jointing electronic parts by using the jointing material. The jointing material consisting of a silver paste comprising silver fine particles, a solvent, 2-butoxyethoxyacetic acid (BEA) as a dispersant and benzotriazole (BTA) as a reaction inhibitor is applied on a copper substrate, mounting an electronic part on the applied jointing material, heating the bonding structure with pressure on the electronic parts to sinter the silver in the silver paste so as to form a silver joint layer and jointing the electronic part to the copper substrate through the silver joint layer.

### SUMMARY OF THE INVENTION

An object of the present invention is to provide a conductive paste sufficiently joints to a mounted electronic component with the conductive paste layer, and a method of manufacturing an electronic device using the conductive paste.

An aspect of the invention relates to a method of manufacturing an electronic device comprising the steps of: preparing a substrate comprising an electrically conductive layer; applying a conductive paste on the electrically conductive layer, wherein the conductive paste comprises 100 parts by weight of a metal powder, 5 to 20 parts by weight of a solvent and 0.01 to 5 parts by weight of a dispersant and wherein the dispersant is selected from the group consisting of allyl ether copolymer, polyhydroxy fatty acid and a mixture thereof; mounting an electrical component on the applied conductive paste; and heating the conductive paste to bond the electrically conductive layer and the electrical component.

Another aspect of the invention relates to a conductive paste for bonding, comprising 100 parts by weight of the metal powder, 5 to 20 parts by weight of a solvent, and 0.01 to 5 parts by weight of a dispersant, wherein the dispersant is selected from the group consisting of allyl ether copolymer, polyhydroxy fatty acid and a mixture thereof.

In an embodiment, the particle diameter (D50) of the metal powder is 0.01 to 3 μm. In an embodiment, the metal powder is selected from the group consisting of silver, copper, gold, nickel, palladium, platinum, rhodium, aluminum, an alloy thereof and a mixture thereof.

In an embodiment, the allyl ether copolymer is a copolymer of a poly carboxylic acid and an ally ether.

In an embodiment, the allyl ether copolymer has one of the following structures:

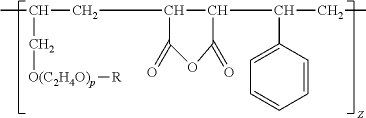

wherein p is 5 to 60, wherein z is 4 to 80 and wherein R is hydrogen or alkyl; or

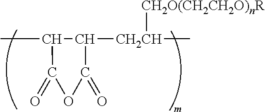

wherein n is 1 to 78, wherein m is 5 to 100, and wherein R is hydrogen or alkyl.

In an embodiment, the polyhydroxy fatty acid has the following structure:

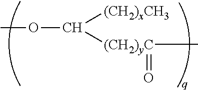

wherein q is 1 to 10, and wherein x+y is 5 to 30.

In an embodiment, wherein the polyhydroxy fatty acid comprises polyhydroxystearic acid.

In an embodiment, the conductive paste further comprises 0.01 to 1.0 parts by weight of a cellulose, a resin or a mixture thereof.

In an embodiment, the electrically conductive layer is a metal layer.

In an embodiment, the electrical component is selected from the group consisting of a semiconductor chip, an integrated circuit (IC) chip, a chip resistor, a chip capacitor, a chip inductor, a sensor chip, and a combination thereof. In an embodiment, the electrical component comprises a metallization layer, and wherein the metallization layer is selected from the group consisting of copper, silver, gold, nickel, palladium, platinum, an alloy thereof and a mixture thereof.

In an embodiment, the heating temperature to bond the electronic component and the conductive layer is 140 to 400° C.

The electronic component can sufficiently adhere to the conductive paste layer before bonding during the manufacturing process by the present invention.

### BRIEF DESCRIPTION OF DRAWINGS

FIG. 1 is a schematic cross-sectional drawing showing an example of a cross section of an electronic device.

### DESCRIPTION OF THE PREFERRED EMBODIMENTS

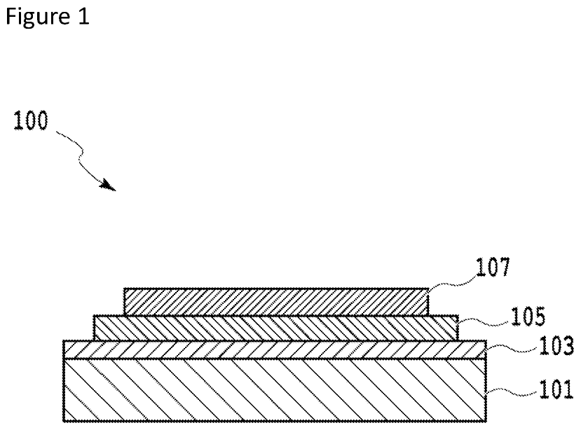

An electric device comprises at least a substrate comprising an electrically conductive layer, a conductive paste layer formed on the conductive layer from a conductive paste, and an electrical component. The electrically conductive layer of the substrate and the electrical component are bonded by the conductive paste. One embodiment of the method of manufacturing an electronic device 100 is explained by referring to FIG. 1. The lower limit value and the upper limit value of the numerical range in an embodiment can be combined with the upper limit value and the lower limit value of the numerical value ranges of the other different embodiments.

(Substrate)

A substrate 101 comprising an electrically conductive layer 103 is prepared. The substrate 101 is not particularly limited and is selected depending on the end application and functions of the electrical component. In an embodiment, the substrate 101 is a silicon substrate, a glass substrate or a ceramic substrate. In an embodiment, the ceramic substrate is an alumina substrate, an aluminum nitride or silicon nitride.

(Conductive Layer)

The conductive layer 103 is a concept comprising a good conductor and a semiconductor. The electrically conductive layer 103 can be an electrical circuit, an electrode or an electrical pad in an embodiment. The electrically conductive layer 103 can be a metal layer in another embodiment. The metal layer can comprise silver, copper, gold, nickel, palladium, platinum, or alloys thereof in another embodiment. The electrically conductive layer 103 can be a copper layer or a silver layer in another embodiment.

(Conductive Paste)

The conductive paste 105 is a conductive paste for bonding. The conductive paste 105 can bond a good conductor and another good conductor, a good conductor and a semiconductor, or a semiconductor and another semiconductor. The conductive paste 105 is applied on the electrically conductive layer 103. The applied conductive paste 105 can be 50 to 500 μm thick in an embodiment, 80 to 300 μm thick in another embodiment, 100 to 200 μm thick in another embodiment. The conductive paste 105 is applied by screen printing in an embodiment. A metal mask can be used for the screen printing in another embodiment.

Major components of the conductive paste 105 are explained below. The conductive paste typically contains a metal powder, a solvent and a dispersant.

(Metal Powder)

The metal powder is selected from the group consisting of silver, copper, gold, palladium, platinum, rhodium, nickel, aluminum, an alloy thereof and a combination thereof in an embodiment. The metal powder is selected from the group consisting of silver, copper, nickel, an alloy thereof and a combination thereof in another embodiment. The metal powder is silver in another embodiment.

The shape of the metal powder is in the form of flake, spherical, amorphous or a mixture thereof in an embodiment. The shape of the metal powder is a mixture of flake and spherical in another embodiment.

The particle diameter (D50) of the metal powder is at least 0.01 μm in another embodiment, at least 0.02 μm in another embodiment, at least 0.03 μm in another embodiment, at least 0.04 μm in another embodiment, at least 0.05 μm in another embodiment, at least 0.07 μm in another embodiment, at least 0.1 μm in another embodiment, at least 0.15 μm in another embodiment, at least 0.2 μm in another embodiment. The particle diameter (D50) of the metal powder is 2 μm or less in another embodiment, 1.8 μm or less in another embodiment, 1.5 μm or less in another embodiment, 1 μm or less in another embodiment, 0.8 μm or less in another embodiment, 0.5 μm or less in another embodiment and 0.3 μm or less in another embodiment. In an embodiment, the metal powder is a mixture of two or more kinds of such powders. With such particle diameter, a good adhesion can be achieved even at a relatively low temperature. The metal particles with the particle diameter can render proper viscosity and rheology as proper distance is maintained between the metal particles due to the attachment of the dispersant onto the metal particles. The particle diameter (D50) is a volume average particle diameter (D50) measured by a laser diffraction method using Microtrac X-100 or by Dynamic Light-Scattering Particle Size Analyzer (LB550, Horiba).

The metal powder is 60 weight percent (wt. %) or more in an embodiment, 72 wt. % or more in another embodiment, 80 wt. % or more in another embodiment, and 85 wt. % or more in another embodiment, based on the total weight of the conductive paste 105. The metal powder is 97 wt. % or less in an embodiment, 95 wt. % or less in another embodiment, 93 wt. % or less in another embodiment, based on the total weight of the conductive paste 105.

(Solvent)

The metal powder disperses in the solvent to form the conductive paste 105. The solvent can be used also for adjusting the viscosity so that the conductive paste 105 can be readily applied onto the substrate 101 or the electrically conductive layer 103. All or most of the solvent evaporates from the conductive paste 105 during the heating step or the optional drying step.

The molecular weight of the solvent is 600 or less in an embodiment, 520 or less in another embodiment, 480 or less in another embodiment, 440 or less in another embodiment, 400 or less in another embodiment, 350 or less in another embodiment, 300 or less in another embodiment, 250 or less in another embodiment, 230 or less in another embodiment, and 200 or less in another embodiment. The molecular weight of the solvent is 10 or more in an embodiment, 100 or more in another embodiment, 120 or more in another embodiment, 140 or more in another embodiment, 150 or more in another embodiment, 180 or more in another embodiment.

The boiling point of the solvent is 100 to 450° C. in an embodiment, 120 to 420° C. in another embodiment, 130 to 410° C. in another embodiment, 140 to 400° C. in another embodiment, 150 to 320° C. in another embodiment, 200 to 290° C. in another embodiment. The solvent is an organic solvent in an embodiment.

The solvent can be selected from the group consisting of 2,2,4-Trimethyl-1,3-pentanediol monoisobutyratetexanol (Texanol™), 1-phenoxy-2-propanol, terpineol, diethylene glycol monoethyl ether acetate (carbitol acetate; Carbitol™), ethylene glycol, diethylene glycol monobutyl ether (butyl carbitol), diethylene glycol dibutyl ether (dibutyl carbitol), dibuthyl acetate propylene glycol phenyl ether, ethylene glycol monobutyl ether, diethylene glycol monobutyl ether acetate (butyl carbitol acetate), 1,2-cyclohexane dicarboxylic acid diisononyl ester, solvent naphtha and a mixture thereof in another embodiment. The solvent can be selected from the group consisting of 2,2,4-Trimethyl-1,3-pentanediol monoisobutyratetexanol (Texanol™), terpineol, diethylene glycol monobutyl ether (butyl carbitol), diethylene glycol monobutyl ether acetate (butyl carbitol acetate), solvent naththa, 1,2-cyclohexane dicarboxylic acid diisononyl ester, and a mixture thereof in another embodiment. The solvent can be selected from the group consisting of 2,2,4-Trimethyl-1,3-pentanediol monoisobutyratetexanol (Texanol™), terpineol, 1,2-cyclohexane dicarboxylic acid diisononyl ester and a mixture thereof in another embodiment.

The viscosity of the conductive paste 105 is, at the shear rate of 10 sec⁻¹, 5 to 300 Pa·s in an embodiment, 9 to 200 Pa·s in another embodiment, 12 to 100 Pa·s in another embodiment, when measuring with a rheometer (HAAKE™ MARS™ III, Thermo Fisher Scientific Inc.) using a titanium cone plate C20/1°.

The solvent is 5 to 20 parts by weight when the metal powder is 100 parts by weight. The solvent is 6.5 parts by weight or more in an embodiment, 7.8 parts by weight or more in another embodiment, 8.8 parts by weight or more in another embodiment when the metal powder is 100 parts by weight. The solvent is 20 parts by weight or less in an embodiment, 18 parts by weight or less in another embodiment, 15 parts by weight or less in another embodiment when the metal powder is 100 parts by weight.

The solvent is 2 wt. % or more in an embodiment, 4 wt. % or more in another embodiment, 6 wt. % or more in another embodiment, and at least 7.5 wt. % or more in another embodiment, based on the total weight of the conductive paste 105. The solvent is 25 wt. % or less in an embodiment, 20 wt. % or less in another embodiment, 15 wt. % or less in another embodiment, based on the total weight of the conductive paste.

(Dispersant)

The dispersant is selected from the group consisting of allyl ether copolymer, polyhydroxy fatty acid and a mixture thereof. Copolymer here means a polymer component comprised of two or more kinds of monomers.

The allyl ether copolymer is a copolymer of a poly carboxylic acid and an ally ether. The poly carboxylic acid is maleic anhydride in an embodiment. The allyl ether is ethylene glycol monoallyl ether in an embodiment. The allyl ether copolymer is a copolymer of a poly carboxylic acid and an ally ether that has a poly carboxylic acid structure in the main chain and an allyl ether structure in the side chain. In this embodiment, other components can be included in the main chain.

The allyl ether copolymer has one of the following structures in an embodiment:

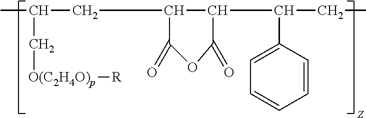

wherein p is 5 to 60, wherein z is 4 to 80 and wherein R is hydrogen or alkyl; or

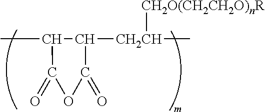

wherein n is 1 to 78, wherein m is 5 to 100, and wherein R is hydrogen or alkyl.

In the above structures, p is 5 or more in an embodiment, p is 6 or more in an embodiment, p is 8 or more in an embodiment, and p is 9 or more in an embodiment. p is 60 or less in an embodiment, p is 56 or less in an embodiment, p is 42 or less in an embodiment, p is 35 or less in an embodiment, p is 30 or less in an embodiment, p is 25 or less in an embodiment, p is 18 or less in an embodiment, p is 15 or less in an embodiment, p is 11 or less in an embodiment. z is 4 or more in an embodiment, z is 6 or more in an embodiment, z is 8 or more in an embodiment, z is 9 or more in an embodiment. z is 80 or less in an embodiment, z is 56 or less in an embodiment, z is 42 or less in an embodiment, z is 35 or less in an embodiment, z is 30 or less in an embodiment, z is 25 or less in an embodiment, z is 22 or less in an embodiment, z is 20 or less in an embodiment.

In the above structures, n is 1 or more in an embodiment, n is 5 or more in an embodiment, n is 6 or more in an embodiment, n is 8 or more in an embodiment. n is 78 or less in an embodiment, n is 65 or less in an embodiment, n is 55 or less in an embodiment, n is 42 or less in an embodiment, n is 35 or less in an embodiment, n is 28 or less in an embodiment, n is 20 or less in an embodiment, n is 16 or less in an embodiment, n is 12 or less in an embodiment. m is 5 or more in an embodiment, m is 6 or more in an embodiment, m is 8 or more in an embodiment, m is 9 or more in an embodiment. m is 100 or less in an embodiment, m is 85 or less in an embodiment, m is 60 or less in an embodiment, m is 51 or less in an embodiment, m is 42 or less in an embodiment, m is 31 or less in an embodiment, m is 25 or less in an embodiment.

In the above structures, R is hydrogen or alkyl in an embodiment. R is hydrogen, methyl, ethyl, propyl, isopropyl, butyl, isobutyl, sec-butyl or tert-butyl in an embodiment. R is hydrogen, methyl, ethyl, propyl or isopropyl in an embodiment. R is hydrogen or methyl in an embodiment. R is hydrogen in an embodiment. R is methyl in an embodiment.

Molecular weight of the allyl ether copolymer is 5,000 to 45,000 in an embodiment, 6,000 to 41,000 in an embodiment, 7,000 to 35,000 in an embodiment, 8,000 to 25,000 in an embodiment, and 10,000 to 20,000 in an embodiment.

The allyl ether copolymer is Malialim™ AKM151160, AKM0531, AAB0851, AFB1521, AWS0851, SC0505K, SC1015F, SC0708A, HKM-50A, HKM-150A (NOF Corporation).

The polyhydroxy fatty acid has the following structure in an embodiment:

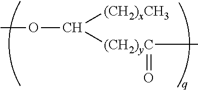

wherein q is 1 to 10, and wherein x+y is 5 to 30.

Molecular weight of the polyhydroxy fatty acid is 100 to 5,000 in an embodiment, 120 to 4,200 in an embodiment, 135 to 3,800 in an embodiment, 150 to 2,800 in an embodiment, 185 to 2,100 in an embodiment, 250 to 1,800 in an embodiment, 280 to 1,500 in an embodiment, 330 to 1,000 in an embodiment, and 400 to 800 in an embodiment.

In the above structure, q is 1 or more in an embodiment, 2 or more in an embodiment, 3 or more in an embodiment. q is 10 or less in an embodiment, 9 or less in an embodiment, 8 or less in an embodiment, 7 or less in an embodiment, 6 or less in an embodiment, 5 or less in an embodiment, 4 or less in an embodiment. x+y is 5 or more in an embodiment, 6 or more in an embodiment, 8 or more in an embodiment, 10 or more in an embodiment, 12 or more in an embodiment. x+y is 30 or less in an embodiment, 28 or less in an embodiment, 22 or less in an embodiment, 19 or less in an embodiment, 17 or less in an embodiment, 16 or less in an embodiment and 15 or less in an embodiment.

The polyhydroxy fatty acid is polyhydroxystearic acid, polyhydroxylauric acid, polyhydroxymyristic acid, polyhydroxypalmitic acid, polyhydroxyoleic acid, or a mixture thereof in another embodiment. The polyhydroxy fatty acid contains polyhydroxystearic acid in an embodiment. The polyhydroxy fatty acid is polyhydroxylauric acid.

The polyhydroxy fatty acid has one of the following structures in another embodiment or a mixture thereof:

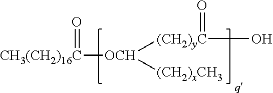

wherein q′ is 0 to 10, and wherein x+y is 5 to 30; or

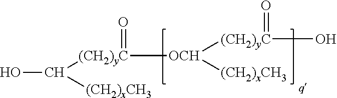

wherein q′ is 0 to 10, and wherein x+y is 5 to 30.

In the above structure, q′ is 0 or more in an embodiment, 1 or more in an embodiment, 2 or more in an embodiment. q′ is 10 or less in an embodiment, 9 or less in an embodiment, 8 or less in an embodiment, 7 or less in an embodiment, 6 or less in an embodiment, 5 or less in an embodiment, 4 or less in an embodiment. x+y is 5 or more in an embodiment, 6 or more in an embodiment, 8 or more in an embodiment, 10 or more in an embodiment, 12 or more in an embodiment. x+y is 30 or less in an embodiment, 28 or less in an embodiment, 22 or less in an embodiment, 19 or less in an embodiment, 17 or less in an embodiment, 16 or less in an embodiment and 15 or less in an embodiment.

A commercially available grade of the polyhydroxy fatty acid is AJISPER™ PA111 (Ajinomoto Fine-Techno Co.,Inc.).

The dispersant is 0.01 to 5.0 parts by weight when the metal powder is 100 parts by weight. The dispersant is 0.1 parts by weight or more in an embodiment, 0.2 parts by weight or more in another embodiment, 0.3 parts by weight or more in another embodiment, 0.4 parts by weight or more in another embodiment, 0.5 parts by weight or more in another embodiment, 0.7 parts by weight or more in another embodiment, and 0.9 parts by weight or more in another embodiment when the metal powder is 100 parts by weight. The dispersant is 3.0 parts by weight or less in an embodiment, 2.0 parts by weight or less in another embodiment, 1.5 parts by weight or less in another embodiment, 1.0 parts by weight or less in another embodiment, 0.7 parts by weight or less in another embodiment and 0.6 parts by weight or less in another embodiment when the metal powder is 100 parts by weight.

Other dispersants than the allyl ether copolymer and the polyhydroxy fatty acid can be included in the conductive paste.

(Cellulose or Resin)

The conductive paste 105 optionally contains a cellulose, a resin or a mixture thereof. The allyl ether copolymer and the polyhydroxy fatty acid are not included in the definition of “resin” herein. A small amount of the cellulose, resin or their mixture can be used to control a viscosity of the conductive paste. The cellulose, resin and their mixture are typically soluble for a solvent. Molecular weight of the cellulose, resin and their mixture is 1,000 or more. Molecular weight of the cellulose, resin and their mixture is 5,000 to 900,000 in an embodiment, 8,000 to 780,000 in an embodiment, 10,000 to 610,000 in an embodiment, 18,000 to 480,000 in an embodiment, 25,000 to 350,000 in an embodiment, and 32,000 to 200,000 in an embodiment. Molecular weight herein, unless otherwise defined, means weight-average molecular weight (Mw). Molecular weight can be measured by, for example, High-performance liquid chromatography (Alliance 2695, Waters Corporation).

The cellulose is selected from the group consisting of ethyl cellulose, methylcellulose, hydroxypropyl cellulose, their derivatives, or a mixture thereof in an embodiment. The cellulose is ethyl cellulose in another embodiment.

Resin is selected from the group consisting of polyvinyl butyral resin, phenoxy resin, polyester resin, epoxy resin, acrylic resin, polyimide resin, polyamide resin, polystyrene resin, butyral resin, polyvinyl alcohol resin, polyurethane resin and a mixture thereof in an embodiment. The polymer is thermoplastic resin in another embodiment.

Glass transition temperature of the cellulose, resin and their mixture is −30 to 250° C. in an embodiment, 10 to 180° C. in another embodiment, 80 to 150° C. in another embodiment.

The cellulose, resin and their mixture is 0.01 parts by weight or more in an embodiment, 0.05 parts by weight or more in another embodiment, 0.1 parts by weight or more in another embodiment, when the metal powder is 100 parts by weight. The cellulose, resin and their mixture is 1.0 parts by weight or less in an embodiment, 0.6 parts by weight or less in another embodiment, 0.4 parts by weight or less in another embodiment, 0.2 parts by weight or less in another embodiment when the metal powder is 100 parts by weight. The small amount of polymer addition can render proper viscosity while keeping the sufficient electrical conductivity of the joint layer.

(Additive)

An additive such as emulsifier, stabilizer and plasticizer can be further comprised in accordance with a desired property of the conductive paste 105. The conductive paste 105 does not comprise a glass frit in an embodiment. The conductive paste 105 does not comprise a curing agent or a cross-linking agent in another embodiment. The conductive paste 105 does not comprise a thermo-setting resin in another embodiment.

(Electrical Component)

The electrical component 107 is mounted on the applied conductive paste 105. The electronic component 107 is not particularly limited as long as it functions electrically. The electrical component 107 can be selected from the group consisting of a semiconductor chip, an integrated circuit (IC) chip, a chip resistor, a chip capacitor, a chip inductor, a sensor chip, and a combination thereof. The electrical component 107 can be a semiconductor chip in another embodiment. The semiconductor chip can be a Si chip or a SiC chip in another embodiment.

The electrical component 107 can comprise a metallization layer in an embodiment. The metallization layer can be selected from the group consisting of copper, silver, gold, nickel, palladium, platinum, alloy thereof and a mixture thereof in another embodiment. The metallization layer comprises gold and/or nickel in another embodiment. The metallization layer comprises a lamination of a gold layer and a nickel layer in another embodiment. The metallization layer is in contact with the layer of the applied conductive paste 105 in case the electrical component 107 comprises a metallization layer in an embodiment. The metallization layer is plating in another embodiment.

The layer of the conductive paste 105 is heated to join the conductive layer 103 and the electrical component 107. The heating temperature can be 140 to 400° C. in an embodiment, 180 to 350° C. in another embodiment, 200 to 300° C. in another embodiment, 220 to 290° C. in another embodiment. Heat damage on the electronic component 107 can be suppressed because the conductive paste 105 can be bonded at a relatively low temperature. Heating time is 1 second or longer in an embodiment, 10 seconds or longer in an embodiment, 30 seconds or longer in an embodiment, 0 seconds or longer in an embodiment, 1 minute or longer in an embodiment, 3 minutes or longer in an embodiment, 5 minutes or longer in an embodiment, 8 minutes or longer in an embodiment, 10 minutes or longer in an embodiment 20 minutes or longer in an embodiment, and 30 minutes or longer in an embodiment. Heating time is 90 minutes or shorter in an embodiment, 70 minutes or shorter in an embodiment, 60 minutes or shorter in an embodiment, 45 minutes or shorter in an embodiment, 30 minutes or shorter in an embodiment, 20 minutes or shorter in an embodiment, 15 minutes or shorter in an embodiment, 10 minutes or shorter in an embodiment, and 5 minutes or shorter in an embodiment.

The heating atmosphere is an inert atmosphere or an air atmosphere in an embodiment. The inert atmosphere is a N₂ atmosphere in another embodiment. The heating atmosphere is the air atmosphere in another embodiment.

Pressure can be optionally applied on the electrical component 107 during the heating in an embodiment. The electrical component 107 can be adhered more to the conductive paste layer 105 by pressure. The pressure can be at least 0.1 MPa in an embodiment, at least 1 MPa in another embodiment, at least 5 MPa in another embodiment, at least 7 MPa in another embodiment, at least 15 MPa in another embodiment, at least 25 MPa in another embodiment. The pressure can be 45 MPa or lower in an embodiment, 40 MPa in another embodiment, 36 MPa or lower in another embodiment, 25 MPa or lower in another embodiment, 15 MPa or lower in another embodiment. The electrical component 107 can be bonded without pressure in another embodiment. A die bonder can be used for heating. The aforementioned heating temperature and time can be adjusted depending on the pressure. For instance, when 10 MPa of pressure is applied, the heating time can be less than 15 minutes.

The applied conductive paste 105 is optionally dried after mounting the electrical component 107 before bonding described above. The drying temperature can be 40 to 150° C. in an embodiment, 0 to 120° C. in another embodiment, 60 to 100° C. in another embodiment. The drying time is 10 to 150 minutes in an embodiment, 15 to 80 minutes in another embodiment, 17 to 60 minutes in another embodiment, 20 to 40 minutes in another embodiment.

The applied conductive paste 105 is optionally preheated after mounting the electrical component 107 before heating for bonding described above. The preheating temperature is 80 to 180° C. in an embodiment, 100 to 170° C. in another embodiment, 120 to 160° C. in another embodiment. The preheating time is 1 second or more in an embodiment, 3 seconds or more in another embodiment. The preheating time is 60 seconds or less in an embodiment, 30 seconds or less in another embodiment, 15 seconds or less in another embodiment, 10 seconds or less in another embodiment. The electrical component 107 can more sufficiently adhere to the surface of the conductive paste layer 105 by the preheating.

Although it's not limited to a specific theory, while the metal powder sinters to join the electrical component 107 and the conductive layer 103 by the heating, the surface of the conductive paste layer 105 contacting the electrical component 107 gets sticky so that the electrical component 107 can relatively firmly adhere to the surface of the conductive layer to be retained on the conductive paste layer 105 without peeling off. An oven or a die bonder can be used for the preheating.

The preheating atmosphere is a N₂ atmosphere or an air atmosphere in an embodiment. The preheating atmosphere is an air atmosphere in another embodiment.

Pre-pressure can be optionally applied on the electrical component 107 during the preheating in an embodiment. The electrical component 107 can be adhered more to the conductive paste layer 105 by the pressure in an embodiment. The pre-pressure can be at least 0.1 MPa in an embodiment, at least 0.5 MPa in another embodiment, at least 1 MPa in another embodiment, at least 2 MPa in another embodiment, at least 3 MPa in another embodiment. The pressure can be 10 MPa or lower in an embodiment, 8 MPa in another embodiment, 6 MPa or lower in another embodiment. The electrical component 107 can adhere to the conductive paste layer 105 without pre-pressure during the preheating in another embodiment. A die bonder can be used for preheating and pre-pressure.

It was found by the inventors that the conductive pastes containing a dispersant selected from the group consisting of allyl ether copolymer, polyhydroxy fatty acid and a mixture thereof can significantly increase adhesion between the electrical component and the conductive paste layer. It is considered that the effect results from the choice of the prescribed dispersants.

Although it's not limited to a specific theory, proper distance is maintained between the metal particles when the dispersant selected from allyl ether copolymer, polyhydroxy fatty acid or a mixture thereof is present in the conductive paste and the dispersants are attached to the metal particles. The metal particles with the particle diameter can render the conductive paste proper viscosity and rheology. Thus, when applied onto the conductive layer, the conductive paste shows a smooth surface with less dimple. Consequently, an increase surface area with less void is formed between the conductive paste 105 and the electrical component 107, resulting in superior adhesion.

### EXAMPLE

The present invention is illustrated by, but is not limited to, the following examples.

The conductive paste of Examples 1 and 2 were prepared as follows.

100 parts by weight of a silver powder was dispersed in 10 parts by weight of a Texanol™ solution to form a conductive paste. The silver powder was a mixture of a spherical silver powder having particle diameter (D50) of 0.4 μm and a flaky silver powder having particle diameter (D50) of 1.6 μm. The Texanol™ solution contained 9.59 parts by weight of Texanol™, 0.4 parts by weight of ethyl cellulose (Ethocel™ N4, Molecular Weight 44,265, Dow Chemical Company) and 0.01 parts by weight of a surfactant. The dispersion was carried out by mixing the components in a mixer followed by a three-roll mill. As the dispersant, the following agents were used.

For Example 1: Malialim™ AKM531 allyl ether copolymer (molecular weight 15,000, NOF Corporation)

For Example 2: Malialim™ AFB1521 allyl ether copolymer (molecular weight 30,000, NOF Corporation)

Control Example 1 that contains no dispersant and Control Examples 2, 3 and 4 that contain one of the following dispersants were similarly prepared.

For Control Example 2: Duemeen™ TDO, N-tallow alkyltrimethylenedi-,oleates (Akzo Nobel)

For Control Example 3: Solsperse™ 71000, polyethylene imine compound having polyether in the side chain (Lubrizol)

For Control Example 4: HIPLAAD™ ED119, mixture of aliphatic carboxylic acid and hydroxyl alkyl amine (Kusumoto Chemicals, Ltd.)

The viscosity of the conductive paste was 15 to 30 Pa·s. The viscosity was measured by a rheometer (HAAKE™ MARS™ III, titanium cone-plate:C20/1°, Thermo Fisher Scientific Inc.).

Next, the conductive paste layer was formed by applying the conductive paste on a copper substrate. Scotch™ tape (Magic™ MP-18 transparent tape, 3M corporation) was put on the copper plate (25 mm wide, 34 mm long, 1 mm thick) with a space of 10 mm. The conductive paste was applied with a scraper over the Scotch™ tape to fill the space with the conductive paste. Then, the Scotch™ tape was peeled off, resulting in the square pattern (10 mm wide, 10 mm long, 150 μm thick) of the conductive paste layer. The conductive paste layer was dried at 80° C. for 30 minutes in an oven.

The adhesion was examined after drying the conductive paste of the square pattern. A copper chip (3 mm wide, 3 mm long, 1 mm thick) was mounted on the upper surface of the square pattern. The copper chip was adhered to the square pattern of the conductive paste layer by using a die-bonder (T-3002M, Tresky AG) under the heating and pressure of 5 MPa/150° C./10 seconds. The adhesion was rated NG when the copper chip dropped off upon upside-down flip. The adhesion was rated OK when the copper chip stack upon upside-down flip. In addition, the adhesion strength of the copper chip was measured by digital force gauge (RZ-10, Aikoh Engineering Co., Ltd.).

The result is shown in Table 1. As shown in Comparative Examples 1 to 4, when the conductive paste contained no dispersion or other types of dispersions (Duomeen™, Solsperse™ or Hiplaad™), the copper chip was easily peeled off and the adhesion strength was null or low. As shown in Examples 1 and 2, the conductive pastes with the Malialim™ dispersion showed good attachment and high adhesion strength.

TABLE 1
(parts by weight)

| | Comp. Ex. 1 | Comp. Ex. 2 | Comp. Ex. 3 | Comp. Ex. 4 | Ex. 1 | Ex. 2 |
|---|---|---|---|---|---|---|
| Ag powder | 100 | 100 | 100 | 100 | 100 | 100 |
| Texanol ™ | 11 | 10 | 10 | 10 | 10 | 10 |
| solution | | | | | | |
| Dispersion | N/A | Duomeen | Solsperse | Hiplaad | Malialim | Malialim |
| | 0 | 1.0 | 1.0 | 1.0 | AKM531 | AFB1521 |
| | | | | | 1.0 | 1.0 |
| Adhesion | 0 | 0 | 0.1 | 0.1 | 0.7 | 0.6 |
| Strength (N) | | | | | | |
| Adhesion | NG | NG | NG | NG | OK | OK |
| Test | | | | | | |

Next, another dispersion was tested for adhesion as Example 3. Polyhydroxy fatty acid (AJISPER™ PA111, Ajinomoto Fine-Techno Co., Inc.) was used as dispersant.

100 parts by weight of a silver powder was dispersed in a mixed solution of 0.4 parts by weight of the dispersant and 11 parts by weight of a Texanol™ solution to form a conductive paste. The silver powder was a mixture of 50 parts by weight of spherical silver powder having particle diameter (D50) of 60 nm and 50 parts by weight of flaky silver powder having particle diameter (D50) of 200 nm. The Texanol™ solution contained 8.5 parts by weight of Texanol™, 2.2 parts by weight of 1,2-cyclohexane dicarboxylic acid diisononyl ester, 0.1 parts by weight of ethyl cellulose (Ethocel™ STD10, Molecular Weight 77,180, Dow Chemical Company) and 0.2 parts by weight of a reducing agent. The dispersion was carried out by mixing the components in a mixer, followed by a three-roll mill. Viscosity of the conductive paste was measured in the same way as Example 1, showing 60 Pa·s.

Square pattern of the conductive paste was formed in the same way as Examples 1 and 2. The copper chip was mounted on the conductive paste and the adhesion procedure was done. The copper chip did not drop off upon upside-down flip, showing good adhesion.

The Examples above show the electrical component mounted on the prescribed conductive layer adheres sufficiently during the manufacturing process, especially before heating to bond.

What is claimed is:

1. A method of manufacturing an electronic device comprising the steps of:
preparing a substrate comprising an electrically conductive layer;
applying a conductive paste on the electrically conductive layer, wherein the conductive paste comprises 100 parts by weight of a metal powder, 5 to 20 parts by weight of a solvent and 0.01 to 5 parts by weight of a dispersant and wherein the dispersant is selected from the group consisting of allyl ether copolymer, polyhydroxy fatty acid and a mixture thereof;
mounting an electrical component on the applied conductive paste; and
subsequent to the step of mounting the electrical component on the applied conductive paste, preheating the applied conductive paste at 80 to 180° C.;
subsequent to the step of preheating the applied conductive paste, heating the conductive paste to bond the electrically conductive layer and the electrical component at 180 to 350° C.

2. The method of claim 1, wherein particle diameter (D50) of the metal powder is 0.01 to 3 μm.

3. The method of claim 1, wherein the metal powder is selected from the group consisting of silver, copper, gold, nickel, palladium, platinum, rhodium, aluminum, an alloy thereof and a mixture thereof.

4. The method of claim 1, wherein the allyl ether copolymer is a copolymer of a poly carboxylic acid and an ally ether.

5. The method of claim 1, wherein the allyl ether copolymer has one of the following structures: 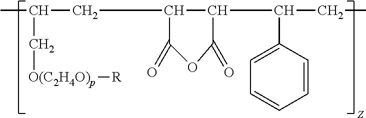
wherein p is 5 to 60, wherein z is 4 to 80 and wherein R is hydrogen or alkyl; or 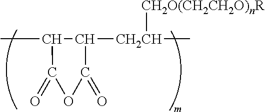
wherein n is 1 to 78, wherein m is 5 to 100, and wherein R is hydrogen or alkyl.

6. The method of claim 1, wherein the polyhydroxy fatty acid has the following structure: 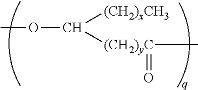
wherein q is 1 to 10, and wherein x+y is 5 to 30.

7. The method of claim 1, wherein the polyhydroxy fatty acid comprises polyhydroxystearic acid.

8. The method of claim 1, wherein the conductive paste further comprises 0.01 to 1.0 parts by weight of a cellulose, a resin or a mixture thereof.

9. The method of claim 1, wherein the electrically conductive layer is a metal layer.

10. The method of claim 1, wherein the electrical component is selected from the group consisting of a semiconductor chip, an integrated circuit (IC) chip, a chip resistor, a chip capacitor, a chip inductor, a sensor chip, and a combination thereof.

11. The method of claim 1, wherein the electrical component comprises a metallization layer, and wherein the metallization layer is selected from the group consisting of copper, silver, gold, nickel, palladium, platinum, an alloy thereof and a mixture thereof.
